(19) United States
(12) Patent Application Publication
(10) Pub. No.: US 2010/0276810 A1
(43) Pub. Date: Nov. 4, 2010

(54) SEMICONDUCTOR DEVICE AND FABRICATION METHOD THEREOF

(75) Inventors: Jui-Chun Chang, Hsinchu City (TW); Ying-cheng Chen, Hsinchu City (TW)

Correspondence Address: QUINTERO LAW OFFICE, PC, 615 Hampton Dr, Suite A202, Venice, CA, 90291, US

(73) Assignee: VANGUARD INTERNATIONAL SEMICONDUCTOR CORPORATION, HSINCHU (TW)

(21) Appl. No.: 12/435,306

(22) Filed: May 4, 2009

(51) Int. Cl. H01L 23/52; H01L 21/768

(52) U.S. Cl. 257/773; 438/675; 257/E23.141; 257/E21.585

(57) ABSTRACT

A semiconductor device is provided. A substrate is provided. A buried layer is formed in the substrate. The buried layer comprises an insulating region. A deep trench contact structure is formed in the substrate. The deep trench contact structure comprises a conductive material and a liner layer formed on a side wall of the conductive material. The conductive material is electrically connected with the substrate.

### BACKGROUND OF THE INVENTION

1. Field of the Invention

The present invention relates to a semiconductor device and a fabrication method thereof, and in particular relates to a deep trench contact structure and a fabrication method thereof.

2. Description of the Related Art

For present semiconductor techniques, an operating single-chip system has been achieved by highly integrating controllers, memory devices, low-operation-voltage circuits, and high-operation-voltage power devices, into a chip. Research development of the power devices, such as vertical double diffused metal oxide semiconductor (VDMOS), insulated gate bipolar transistor (IGBT), lateral double diffused metal oxide semiconductor (LDMOS), or etc., has focused on increasing efficiency to decrease energy loss of the devices. Meanwhile, high voltage transistors and the low voltage CMOS circuits are integrated into a chip, thus isolation structures are formed for isolating adjacent devices.

FIG. 1 is a cross-section view illustrating a semiconductor device as known in the art. A deep trench insulator 20, formed of dielectric material, is usually used for isolating adjacent devices. Thus, power parameters of the isolated devices can be controlled, respectively. However, spurious capacitance occurs easily in the deep trench insulator 20, and a buried oxide layer 30 between an active region and a substrate 10. When the device is operated under a voltage, especially high voltage, coupling effect occurs due to charging of the spurious capacitance described above. The spurious coupling effect not only influences adjacent devices, but also influences other electrical connected devices of the substrate.

Continuing advances in semiconductor manufacturing processes have resulted in semiconductor devices with precision features and/or higher degrees of integration. However, with higher device speeds, it has become more difficult to control spurious capacitance or spurious resistance, thus hindering frequency improvement of the devices. The hindering effect is also called resistive capacitive delay (RC delay). RC delay results in not only hindering further increase of device speeds, but also exacerbates unnecessary energy loss. The effects described above influence not only working status but also stability of devices. RC delay is a major issue for semiconductor devices with higher speeds and lower tolerating noise of the devices.

As such, a semiconductor and a fabrication method thereof are needed.

### BRIEF SUMMARY OF INVENTION

A detailed description is given in the following embodiments with reference to the accompanying drawings.

The invention provides a semiconductor device. A substrate is provided. A buried layer is formed in the substrate. The buried layer comprises an insulating region. A deep trench contact structure is formed in the substrate. The deep trench contact structure comprises a conductive material and a liner layer formed on a side wall of the conductive material. The conductive material is electrically connected with the substrate.

The invention provides a method for fabricating a semiconductor device. A substrate with a buried layer therein is provided. The buried layer comprises an insulating region. A deep trench contact structure is formed in the substrate. The deep trench contact structure comprises a conductive material and a liner layer formed on a side wall of the conductive material. The conductive material is electrically connected with the substrate.

### BRIEF DESCRIPTION OF DRAWINGS

The present invention can be more fully understood by reading the subsequent detailed description and examples with references made to the accompanying drawings, wherein:

FIG. 1 is a cross-section view illustrating a semiconductor device as known in the art.

FIGS. 2 to 9 are cross-section views illustrating an embodiment of the method for fabricating the semiconductor device.

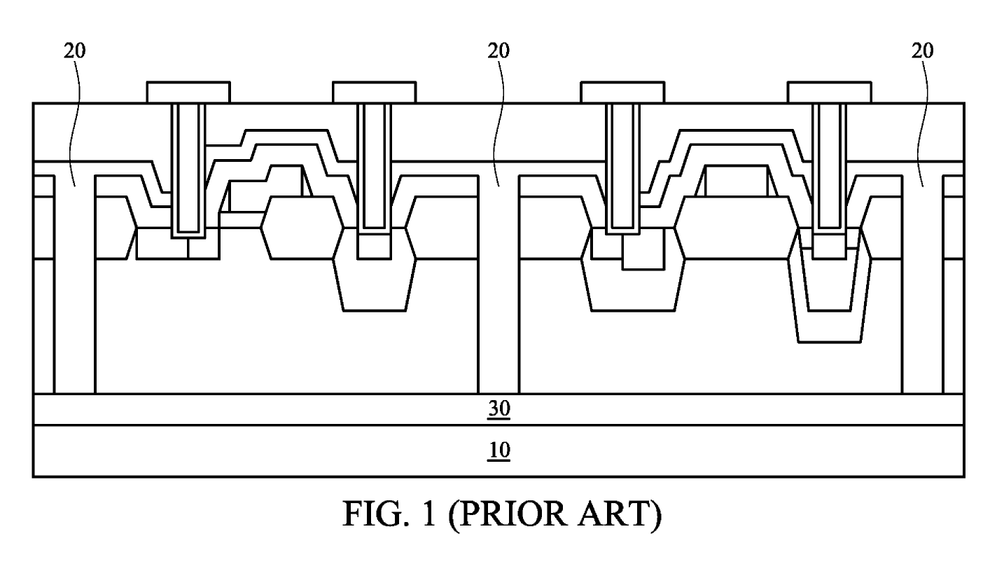

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

Embodiments of the present invention provide a semiconductor device and a method for forming a semiconductor device. References will be made in detail to the present embodiments, examples of which are illustrated in the accompanying drawings. Wherever possible, the same reference numbers are used in the drawings and the descriptions to refer to the same or like parts. In the drawings, the shape and thickness of one embodiment may be exaggerated for clarity and convenience. The descriptions will be directed in particular to elements forming a part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

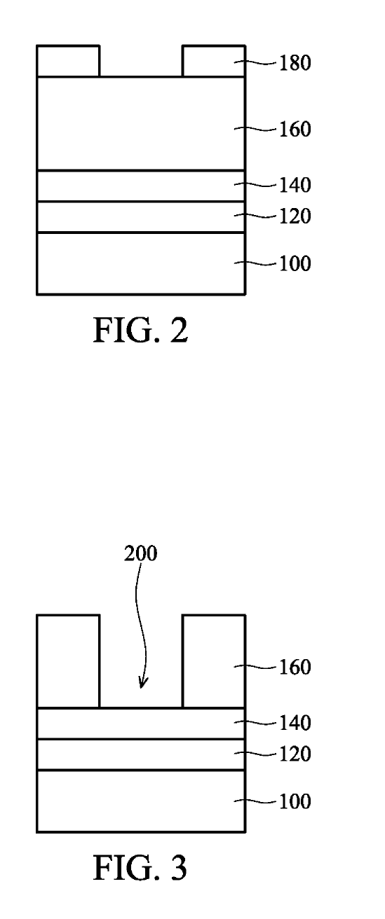

FIGS. 2 to 9 are cross-section views illustrating an embodiment of the method for fabricating the semiconductor device. Referring to FIG. 2, a substrate 100 is provided. A conductive buried layer 120, an insulating buried layer 140, and an epitaxial layer 160 are formed on the substrate 100. The substrate 100 may comprise silicon or other suitable semiconductor material. The insulating buried layer 140 may comprise oxide, such as silicon dioxide. After forming a mask layer 180 on the epitaxial layer 160, the mask layer 180 is patterned to expose a surface of the epitaxial layer 160. In one embodiment, a resistance of the conductive buried layer 120 is less than a resistance of the substrate 100. In other embodiments, since the resistance of the substrate is minimal, the conductive buried layer is not formed (not shown).

Referring to FIG. 3, after forming the patterned mask layer 180 on the epitaxial layer 160, the epitaxial layer 160 exposed by the mask layer 180 is removed by an etching process to form a first deep trench 200 exposing a top surface of the insulating buried layer 140. In other embodiments, the epitaxial layer 160 exposed by the mask layer 180 and a portion of the insulating buried layer 140 under the epitaxial layer 160 are removed by an etching process, not shown, to form the first deep trench 200 exposing a part the insulating buried layer 140 under the top surface of the insulating buried layer 140. The mask layer 180 is then removed.

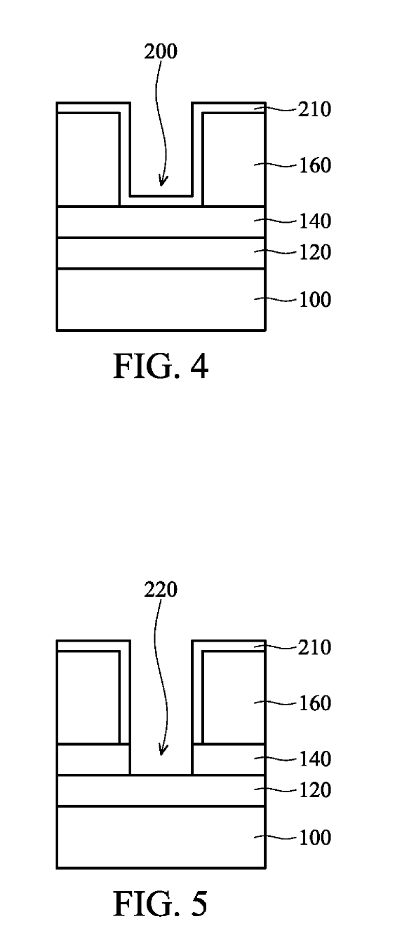

Referring to FIG. 4, after forming the first deep trench 200, a liner layer 210 is formed on a side wall and a bottom surface of the first deep trench 200. The liner layer 210 may be extended to a top surface of the epitaxial layer 160. The liner layer 210 may comprise an oxide, such as tetra-ethyl-ortho-silicate (TEOS) based oxide. Then, the liner layer 210 on the insulating buried layer 140 exposed by the first deep trench 210 is removed by an etching process. After removing the liner layer 210, the etching process may be continued to remove the insulating buried layer 140 exposed by the first deep trench 200 to form a second deep trench 220 under the first deep trench 200 as shown in FIG. 5. The liner layer 210 on the side wall of the first deep trench 220 may be remained. Referring to FIG. 5, the second deep trench 220 exposes a top surface of the conductive buried layer 120. In other embodiments, after removing the insulating buried layer 140, the etching process may be continued to remove a portion of the conductive buried layer 120 exposed by the first deep trench 200 to form the second deep trench 220 exposing a part of the conductive buried layer 120 below a top surface of the conductive buried layer 120 (not shown). In one embodiment, since the conductive buried layer 120 is not formed, the second deep trench 220 exposes a top surface of the substrate 100 or a part below the top surface of the substrate 100 under the insulating buried layer 140.

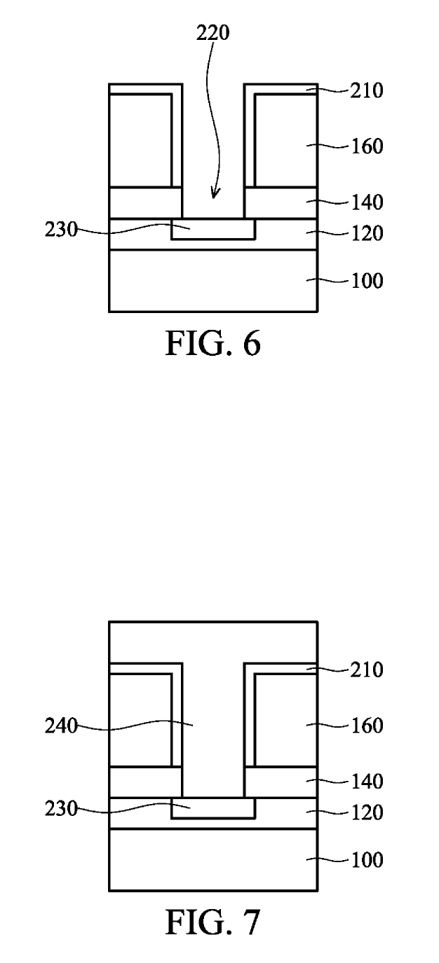

Referring to FIG. 6, a doped region 230 is formed in the conductive buried layer 120 exposed by the second deep trench 220 by ion implantation. Then, the doped region 230 may be annealed to make doped ions diffuse laterally and vertically. For example, the doped ions in the doped region 230 may diffuse laterally into the conductive buried layer 120 under the insulating buried layer 140, and diffuse vertically into a deeper portion of the conductive buried layer 120 as shown in FIG. 6. The doped region 230 and the conductive buried layer 120 may have the same conductivity type. In one embodiment, the doped region 230 and the conductive buried layer 120 have N-type conductivity. A dopant concentration of the doped region 230 is usually higher than a dopant concentration of the conductive buried layer 120. The doped region 230 provides a higher dopant uniformity to form a better interface resistance/capacity and a more stable (ohm contact) conductive element. In other embodiments, as the resistance of the substrate 100 is minimal, the conductive buried layer 120 may not be formed, and thus the doped region 230 may be formed in the substrate 100 exposed by the second deep trench 220 (not shown). In one embodiment, the doped region 230 may not be formed.

Referring to FIG. 7, after forming the doped region, a conductive material 240 is formed to fill the first deep trench 200 and the second deep trench 220. The conductive material 240 may be extended into a surface of the liner layer 210. The conductive material 240 may comprise doped polysilicon. In an embodiment, the conductive material 240 is a doped polysilicon formed by an in-situ chemical vapor deposition process in an environment having dopant vapors. The conductive material 240, the doped region 230, and the conductive buried layer 120 may have the same conductivity type. In one embodiment, the conductive material 240, the doped region 230, and the conductive buried layer 120 have N-type conductivity. In an embodiment, the conductive material 240 is an N-type doped polysilicon. In other embodiments, the conductive material 240 may comprise a metal, such as tungsten, or aluminum.

With increasing crystal lattice differences of the oxide of the liner layer 210 and the epitaxial layer 160, a stress occurs easily in an interface between the liner layer 210 and the epitaxial layer 160. A structural defect may be formed due to increasing crystal lattice differences following a high temperature process. By choosing a doped polysilicon as a conductive material 240 the stress between the materials may be buffered, thus improving the stability and the efficiency of devices.

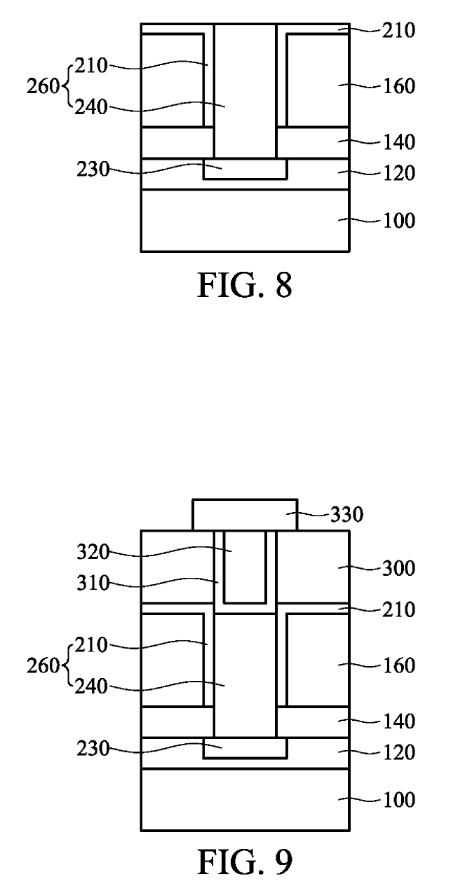

Referring to FIG. 8, the conductive material 240 above the liner layer 210a is removed by an etching back process to form a deep trench contact structure 260.

Since the doped polysilicon conductive material 240 of the deep trench contact structure 260 is formed by the in-situ chemical vapor deposition process in the environment having dopant vapors without an additional doping, pollution due to the doping process and decreased efficiency of devices can be avoided. Thus, the deep trench contact structure 260 can be deposited closer to a major element. since the liner layer 210, comprising an oxide having insulating function, is formed on the sidewall of the deep trench contact structure 260, the deep trench contact structure 260 can be formed as an isolation structure for isolating devices. In one embodiment, the deep trench contact structure 260 can be used to define an active region of a device. In other embodiments, the deep trench contact structure 260 and the insulating buried layer 140 can be used to define an active region of a device.

Referring to FIG. 9, after forming the deep trench contact structure 260, an inter-layer dielectric 300 is formed on the deep trench contact structure 260 and the liner layer 210. A contact plug 320, passing through the inter-layer dielectric 300 and electrically connected to the deep trench contact structure 260, is then formed. The contact plug 320 may be a tungsten plug. In one embodiment, the contact plug 320 may have a barrier layer 310, such as titanium or titanium oxide, formed on a sidewall and a bottom of the contact plug 320. A metal layer 330 may be formed on the contact plug 320. The conductive buried layer 120, doped region 230, and deep trench contact structure 260 can be electrically externally connected by the contact plug 320 and metal layer 330.

Since the conductive buried layer 120, doped region 230, and deep trench contact structure 260 are electrically connected to an external power source by the contact plug 320 and metal layer 330, a spurious charge, induced in the insulating buried layer 140 and the liner layer 210 when operating the device, can be externally transferred by the conductive buried layer 120 (or the substrate 100) adjacent to the insulating buried layer 140 and the liner layer 210, and by the conductive material 240 with the grounding external power source electrically connected with the conductive material 240, conductive buried layer 120 (or substrate 100), and doped region 230. Thus, noise due to spurious capacitance can be avoided. The voltage of the conductive buried layer 120 (or the substrate 100) can be externally controlled through the deep trench contact structure 250.

The embodiments of the invention have several advantages, for example, a method is provided for forming a semiconductor device, comprising forming a deep trench contact structure in a substrate with an insulating buried layer and a conductive buried layer formed therein. The deep trench contact structure comprises a conductive material and a liner layer formed on a sidewall of the conductive material.

Since the conductive material of the deep trench contact structure is formed by the in-situ chemical vapor deposition process in the environment having dopant vapors without an additional doping process, pollution due to doping and decreased efficiency of the device can be avoided, and thus, the deep trench contact structure can be deposited closer to a major element. Since the liner layer, comprising an oxide having insulating function, is formed on the sidewall of the deep trench contact structure, the deep trench contact structure can be formed as an isolation structure for isolating devices, and thus, an area of an active region for forming a device can be reduced. As described above, the method for forming the deep trench contact structure according to the embodiments of the invention can increase the number of devices fabricated in one wafer, and thus, device density can be increased. By choosing a doped polysilicon as the conductive material, stress due to increasing crystal lattice differences of the liner layer comprising oxide and the epitaxial layer can be buffered, and stability and efficiency of the device can thus be improved.

The conductive material of the deep trench contact structure, the conductive buried layer (or substrate), and the doped region can be electrically externally connected by the contact plug and the metal layer. Therefore, noise due to spurious capacitance can be avoided, while a spurious charge, induced in the insulating buried layer or the liner layer when operating the device, can be externally transferred by the conductive material, conductive buried layer (or substrate) and doped region. The voltage of the conductive buried layer (or substrate) can be externally controlled through the deep trench contact structure. The doped region can provide higher dopant uniformity to form a better interface resistance/capacity and a more stable (ohm contact) conductive element between the conductive buried layer (or the substrate) and the conductive material of the deep trench contact structure.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a buried layer formed in the substrate, wherein the buried layer comprises an insulating region; and
a deep trench contact structure formed in the substrate, wherein the deep trench contact structure comprises a conductive material and a liner layer formed on a side wall of the conductive material, and the conductive material is electrically connected with the substrate.

2. The semiconductor device as claimed in claim 1, wherein the liner layer comprises oxide.

3. The semiconductor device as claimed in claim 1, wherein the conductive material comprises doped polysilicon.

4. The semiconductor device as claimed in claim 1, further comprising a doped region formed between the deep trench contact structure and the substrate.

5. The semiconductor device as claimed in claim 1, wherein the buried layer further comprises a conductive region.

6. The semiconductor device as claimed in claim 5, wherein the conductive material is electrically connected with the conductive region.

7. The semiconductor device as claimed in claim 5, wherein the conductive region is formed under the insulating region.

8. The semiconductor device as claimed in claim 5, further comprising a doped region formed between the deep trench contact structure and the buried layer.

9. The semiconductor device as claimed in claim 8, wherein the doped region is formed between the conductive material and the conductive region.

10. A method for fabricating a semiconductor device, comprising:
providing a substrate with a buried layer therein, wherein the buried layer comprises an insulating region; and
forming a deep trench contact structure in the substrate, wherein the deep trench contact structure comprises a conductive material and a liner layer formed on a side wall of the conductive material, and the conductive material is electrically connected with the substrate.

11. The method for fabricating the semiconductor device as claimed in claim 10, further comprising forming a doped region between the deep trench contact structure and the substrate.

12. The method for fabricating the semiconductor device as claimed in claim 10, wherein the buried layer further comprises a conductive region.

13. The method for fabricating the semiconductor device as claimed in claim 12, wherein the conductive region is formed under the insulating region.

14. The method for fabricating the semiconductor device as claimed in claim 12, further comprising forming a doped region between the deep trench contact structure and the buried layer.

15. The method for fabricating the semiconductor device as claimed in claim 14, wherein the doped region is formed between the conductive material and the conductive region.

16. The method for fabricating the semiconductor device as claimed in claim 10, wherein a method for forming the deep trench contact structure comprises:
forming a first deep trench in the substrate to expose the buried layer;
forming the liner layer on a side wall of the first deep trench;
forming a second deep trench in the buried layer, wherein the second deep trench is formed under the first deep trench and communicates with the first deep trench; and
forming the conductive material to fill the first deep trench and the second deep trench.

17. The method for fabricating the semiconductor device as claimed in claim 16, wherein the first deep trench exposes the insulating region.

18. The method for fabricating the semiconductor device as claimed in claim 16, wherein the second deep trench exposes the substrate.

19. The method for fabricating the semiconductor device as claimed in claim 18, further comprising forming a doped region in the substrate exposed by the second deep trench.

20. The method for fabricating the semiconductor device as claimed in claim 16, wherein the buried layer further comprises a conductive region.

21. The method for fabricating the semiconductor device as claimed in claim 20, wherein the second deep trench exposes the conductive region.

22. The method for fabricating the semiconductor device as claimed in claim 21, further comprising forming a doped region in the conductive region exposed by the second deep trench.

23. The method for fabricating the semiconductor device as claimed in claim 16, wherein a method for forming the liner layer on the side wall of the first deep trench comprises:
forming the liner layer on a bottom and the side wall of the first deep trench; and
removing the liner layer on the bottom of the first deep trench to leave the liner layer on the side wall of the first deep trench.
